(19) United States
(12) Patent Application Publication
(10) Pub. No.: US 2005/0076282 A1
(43) Pub. Date: Apr. 7, 2005

(54) System and method for testing a circuit design

(76) Inventors: Ryan Clarence Thompson, Loveland, CO (US); John Warren Maly, Laporte, CO (US); Zachary Steven Smith, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/676,859

(22) Filed: Oct. 1, 2003

(51) Int. Cl. G06F 11/00; G01R 31/28

(52) U.S. Cl. 714/739

(57) ABSTRACT

A system and method for testing a circuit design using a test generator. In one embodiment, a random number generator, responsive to a seed, generates a random number sequence and an event probability generator, responsive to profile settings, generates a probability profile. The test generator, responsive to the random number sequence and the probability profile, generates a test case that includes settings indicative of the seed and the profile settings. An extraction and regeneration engine extracts the seed and the profile settings from the test case in order to reconstitute a test case designed to avoid illegal test behavior.

### CROSS-REFERENCE TO RELATED APPLICATION(S)

This application discloses subject matter related to the subject matter disclosed in the following commonly owned co-pending patent applications: “System and Method for Generating a Test Case,” filed ______, Application No.: ______ (Docket Number 200209280-1), in the names of Ryan C. Thompson, John W. Maly, and Zachary S. Smith; and “System and Method for Building a Test Case Including A Summary of Instructions,” filed ______, Application No.: ______ (Docket Number 200208930-1), in the names of Ryan C. Thompson, John W. Maly, and Adam C. Brown, both of which are hereby incorporated by reference for all purposes.

### BACKGROUND

The design cycle for a digital integrated circuit is long and expensive. Once the first chip is built, it is very difficult, and often impossible, to debug it by probing internal connections or to change the gates and interconnections. Usually, modifications must be made in the original design database and a new chip must be manufactured to incorporate the required changes. Since this process can take months to complete, chip designers are highly motivated to attempt to perfect the chip prior to manufacturing.

It is therefore essential to identify and quantify the architectural requirements necessary to assure good performance over a wide range of events prior to manufacturing the digital integrated circuit. Accordingly, a simulator comprising program code may be employed to provide a simulation environment that is executable on top of a host computer platform in order to model at least some or all of the functionalities of the desired integrated circuit, for example, a target processor core. The characteristics of the target processor core that the simulator emulates may be specified to include processor architectural model, processor clock speed, cache configuration, disk seek time, memory system bus bandwidth, and numerous other parameters. The resulting software-based target processor core provides the appearance of being a normal processor core while a test generator exercises the target processor core with test cases in order to collect detailed hardware behavior data only available through the use of the simulation. In particular, inputs supplied the test generator define specific hardware functionalities to be tested. The resulting test files the test generator gathers may be subsequently utilized to better understand various aspects of the simulated target processor's core.

By modeling the processor core, simulation is able to provide an accurate behavioral paradigm that allows each aspect of the simulated processor core's functionality to match that of a specific target processor core. As a result, simulations can provide visibility that translates into detailed information regarding the various aspects of a target processor core's execution behavior. Simulators are not without limitations, however. Test generators often generate test cases containing illegal test behavior and require debugging. As a result, once the test generator has been debugged, the inputs provided the test generator must be laboriously reconstructed so that the target processor core may be retested.

### SUMMARY

A system and method are disclosed that provide for testing a circuit design using a test generator. In one embodiment, a random number generator, responsive to a seed, generates a random number sequence and an event probability generator, responsive to profile settings, generates a probability profile. The test generator, responsive to the random number sequence and the probability profile, generates a test case that includes settings indicative of the seed and the profile settings. An extraction and regeneration engine extracts the seed and the profile settings from the test case in order to reconstitute a test case designed to avoid illegal test behavior.

### BRIEF DESCRIPTION OF THE DRAWINGS

FIG. 1 depicts a block diagram of an embodiment of a system for simulating target processor core models that can be exercised by an Automatic Test Generator (ATG);

FIG. 2 depicts a block diagram of an embodiment of a system for testing a circuit design using an ATG;

FIG. 3 depicts a block diagram of an embodiment of an extraction and regeneration engine operable to extract data from a test structure in order to reconstruct test case inputs;

FIG. 4 depicts a flow chart of an embodiment of a method of testing a circuit design using an ATG; and

FIG. 5 depicts a flow chart of one embodiment of a method of debugging an ATG.

### DETAILED DESCRIPTION OF THE DRAWINGS

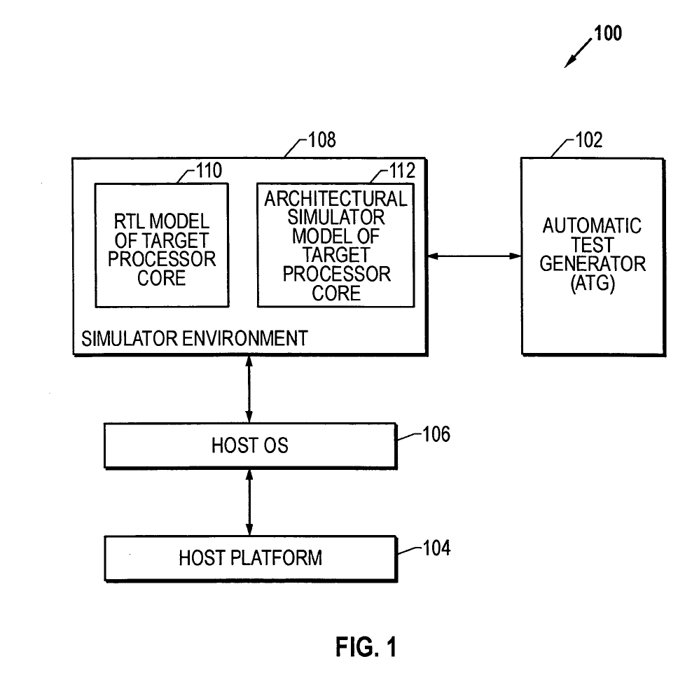

In the drawings, like or similar elements are designated with identical reference numerals throughout the several views thereof, and the various elements depicted are not necessarily drawn to scale. Referring now to FIG. 1, therein is depicted an embodiment of a system 100 for simulating target processor core models that can be exercised by an Automatic Test Generator (ATG) 102. A host platform 104 includes a host OS 106 executing thereon that is operable to provide a software platform. A simulator environment 108 is provided as a software rendition capable of running on the host OS 106, and may be embodied as one or more simulated target instances that define a simulated environment. As illustrated, the simulator environment includes a Register-Transfer Level (RTL) model 110 of the target processor core and an architectural simulator model 112 of the target processor core. As will be explained in further detail hereinbelow, the ATG 102, responsive to input settings, generates a test case that exercises the behaviors and functionalities of the RTL model 110 and the architectural simulator model 112. The resulting test files are then utilized to understand the behavior of the target processor core.

The RTL model 110 and the architectural simulator model 112 may simulate any processor core having any configuration or digital design. For example, the target processor core may simulate a two-core processor system wherein each processor is capable of parallel instruction processing, i.e., multi-threading, that delivers high availability and scalability with a wide breadth of enterprise application capabilities. It should be appreciated that depending on the design and verification objectives, the simulator environment 108 may include other types of target processor core models.

The RTL model 110 simulates the target processor core by utilizing a hardware-description language (HDL) that specifies the signal and gate-level behavior of the target processor core. The architectural simulator model 112, on the other hand, provides a higher level of abstraction than the RTL simulator model 110 in order to model the target processor core in terms of a high-level architecture that defines system-level behavioral functionalities of the target processor core. The RTL model 110 may be designed with the aid of computer-aided design (CAD) software tools, also referred to as computer-aided engineering (CAE) software tools, that assist in the development of the conceptual and physical design of the IC as well as the verification of the IC.

Sophisticated CAD software tools contain component libraries and component models that describe in detail the logical and electrical operations of the digital system design of the IC. Using these models, the IC design may be verified so that various types of logic and timing errors may be found by the test generator during the pre-silicon simulation phase of development. Specifically, the RTL model 110 may be designed by a schematic editor in a highly capable HDL environment such as a Very High Speed Integrated Circuit (VHSIC) hardware description language (VHDL) environment, a Verilog description language environment, or an Advanced Boolean Equation Language (ABEL) environment, for example. The HDL language environment provides a design, simulation, and synthesis platform wherein each constituent component within the design can be provided with both a well-defined interface for connecting it to other components and a precise behavioral specification that enables simulation. The architectural model 112, on the other hand, may be implemented in a higher-level language such as C or C++.

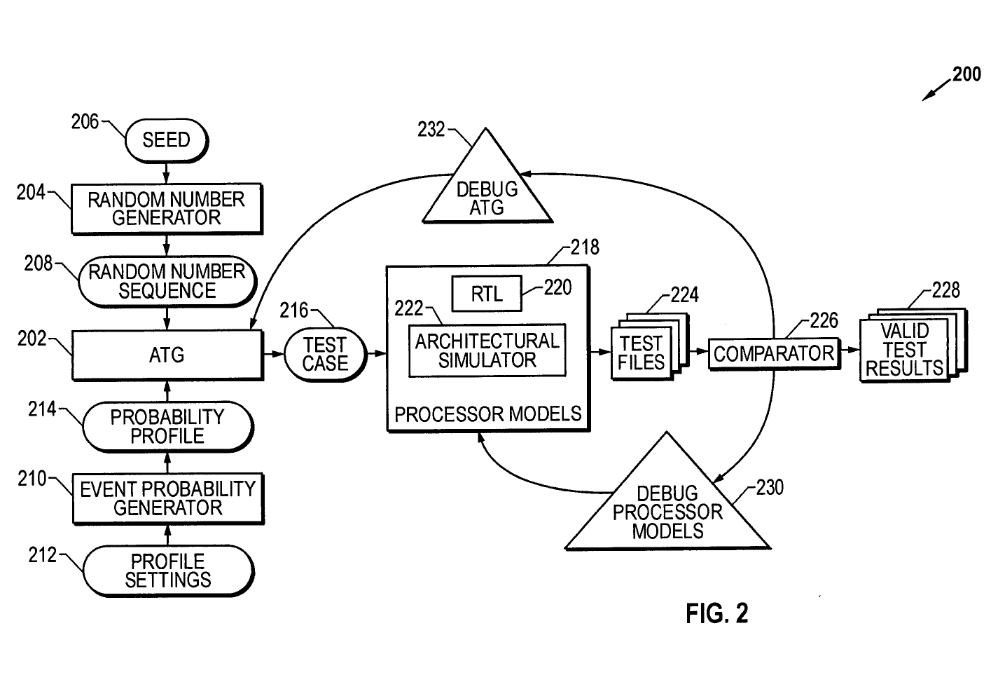

FIG. 2 depicts a system 200 for testing a circuit design using an ATG 202 according to one embodiment of the invention. A random number generator 204, responsive to a seed 206, generates a random number sequence 208. In one embodiment, if the seed is a number A, the random number generator 204 generates the random number sequence 208 {A₁, A₂, A₃, . . . , Aₙ}. By way of another example, if the seed 206 provided to the random number generator 204 is B, then the random number sequence 208 generated is {B₁, B₂, B₃, . . . , Bₘ}. Hence, the random number sequence 208 may be considered a function of the seed 206. In another embodiment, the random number sequence 208 may be considered a random sequence of numbers that are “predetermined” based upon the seed 206.

An event probability generator 210, responsive to profile settings 212, generates a probability profile 214. The profile settings 212 are user configurable settings which define the frequency or occurrence of the events that will exercise the processor models. Events include data operations such as loading, storing, and arithmetic operations, for example. Moreover, events include other performance-based operations such as the selection of parameters related to floating-point representations of numbers. The event probability generator 210 reconstitutes the profile settings 212 into the probability profile 214 which defines a set of event-related parametrics that will be accepted by the ATG 202.

The ATG 202, responsive to the random number sequence 208 and the probability profile 204, generates a test case 216 in order to exercise the processor models 218. Additionally, command line settings may be provided to the ATG 202 and employed by the ATG 202 in the generation of the test case 216. Command line settings relate to the starting and stopping of specific actions in the processor models 218 and the defining of testing conditions, such as the number of threads, for example. In one embodiment, the ATG 202 embeds settings indicative of the seed 206, the profile settings 212, and the command line settings within the test case 216. Further information regarding the generation of test cases, especially those involving multithreading, may be found in the aforementioned patent application entitled “System and Method for Generating a Test Case,” filed ______, Application No.: ______ (Docket Number 200209280-1), in the names of Ryan C. Thompson, John W. Maly, and Zachary S. Smith, which is hereby incorporated by reference for all purposes.

As illustrated, the test case 216 exercises an RTL model 220 and an architectural simulator model 222. The results of the exercises are stored as test files 224. Included in the data in the test files 224 are settings indicative of the seed 206, the profile settings 212, and the command line settings. As will be discussed in more detail hereinbelow, the embedded settings in both the test case 216 and the test files 224 are indicative of the seed 206, the profile settings 212, and the command line settings. Either the test case 216 or the test files 224 may provide an extraction and regeneration engine the information necessary to reconstruct the inputs supplied to the ATG 202 so that the ATG 202 may be debugged or a modified ATG can rerun the test with the identical inputs. A comparator 226, which may be a programmer, a group of programmers, an expert system, or any combination thereof, examines the content of test files 224 to determine if the test results are valid or invalid. In particular, the comparator 226 examines and compares the results provided by the RTL model 220 and the results provided by the architectural simulator model 222. As previously discussed, the RTL model 220 simulates register-level events in the target processor core. The RTL model, therefore, serves as a verification tool for the architectural simulator 222. Additionally, the comparator 226 examines the output provided by the RTL model 220 and the architectural simulator 222 to determine if an illegal test behavior has occurred.

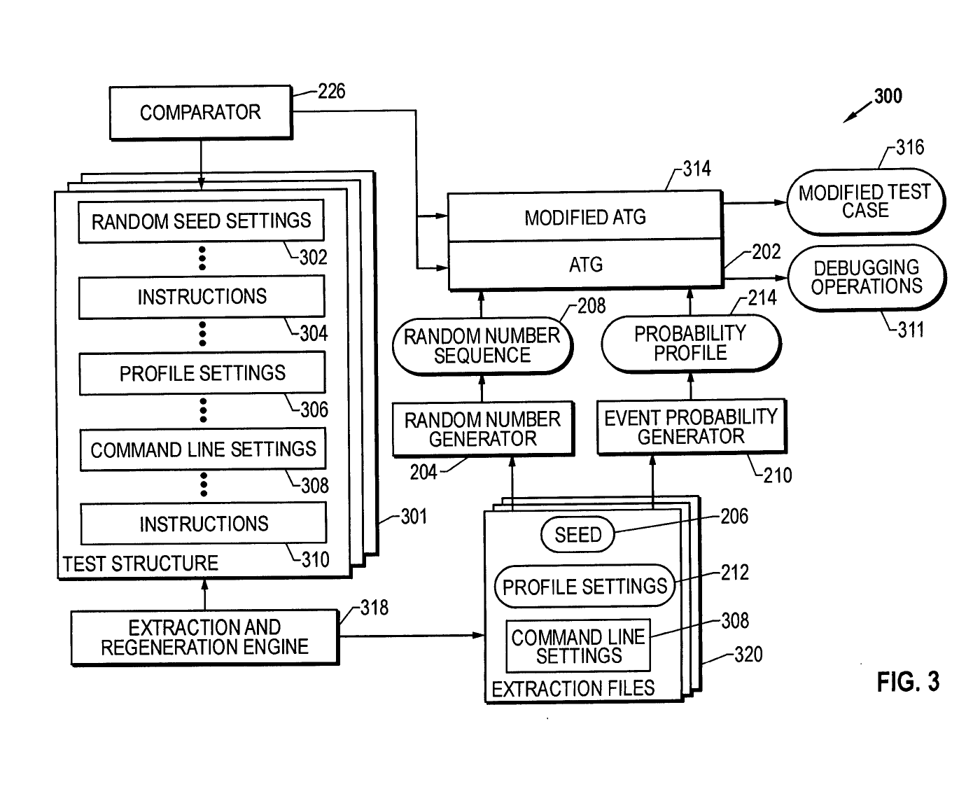

If the test files are valid, i.e., the RTL model 220 verifies the architectural simulator model 222 and the test files 224 do not contain illegal test behavior, the test files 224 become valid test results 228 which provide detailed information regarding each exercised aspect of the target processor core's execution behavior. On the other hand, if the test files 224 indicate processor model inconsistences between the RTL model 220 and architectural simulator 222, then a debugging operation 230 may be required with respect to the processor models. Debugging the architectural simulator and RTL models may involve diagnosing and resolving the problem according to conventional techniques. For example, by examining the test files 224 and underlying HDL-based code of the RTL model 220, a clear understanding of the symptoms of the problem may be achieved. Then all of the variables that affect the problem may be identified and the variables progressively eliminated until the root cause of the problem is isolated. Once the root cause is isolated, the HDL-based code of the models may be appropriately modified to eliminate the problem. If the test files 224 indicate the presence of an illegal test behavior, however, the ATG 202 requires a debugging operation 232 which will be described more fully with particular reference to FIG. 3 hereinbelow. An illegal test behavior may involve a request to perform an illegal operation such as the simultaneous storing and reading of data in a particular register. For example, the ATG may incorrectly instruct the test case to read data at a particular register while the data is being stored at that register, thereby creating an illegal test behavior.

FIG. 3 depicts one embodiment of a parametric extraction and regeneration system 300 for effectuating the ATG debugging operation 232 illustrated in FIG. 2. In order to troubleshoot the ATG 202 that has created an illegal test behavior, the comparator 226, e.g., the programmer or group of programmers, systematically examines a test structure 301 which may be the test case 216 in one embodiment or the test files 224 in another embodiment. As illustrated, test structure 301 include random seed settings 302, instructions 304, profile settings 306, command line settings 308, and instructions 310, for example. In particular, with respect to performing debugging operations 311 on the ATG 202, the comparator 226 will examine the test structure in detail in order to facilitate the generation of reconstituted test cases based on extracted test case parametrics. The troubleshooting techniques employed to determine the cause of the illegal test behavior may be similar to the aforementioned techniques employed in relation to debugging the processor models. Additionally, the troubleshooting techniques may involve setting break-points, for example, in order to isolate the code portion responsible for the illegal test behavior. In particular, the debugging operations 311 will involve an extraction and regeneration engine 318 extracting the seed 206, profile settings 212, and command line settings 308 from the test structure 310, which may be the test case 216. As will be explained in more detail hereinbelow, the seed 206, profile settings 212, and command line settings 308 form extraction files 320 which serve as reconstituted input parameters to the random number generator 204 and event probability generator 210 such that the random number sequence 208 and probability profile 214 originally provided may be presented again to the ATG 202 to facilitate its debugging. Once the problem in the ATG is isolated, the comparator 226 is operable to modify or otherwise add applicable functionality to the ATG 202 to correct the cause of the illegal test behavior. The result of the modification, i.e., modified ATG 314, is operable to create a modified test case 316 and exercise the processor models with the modified test case 316 in order to ensure that the illegal test behavior has been eliminated.

In order to generate the modified test case 316 that corresponds to the original test case, however, the modified ATG 314 must be supplied with the same random number sequence 208 and probability profile 214. The extraction and regeneration engine 318 traverses the test structure 301, which may be the test case 216 or the test files 224, to extract the random seed settings 302, profile settings 306, and command line settings 308. Based on the extracted settings 302, 306, and 308, the extraction and regeneration engine 318 places the seed 206, the profile settings 212, and command line settings 308 in one or more extraction files 320. In one embodiment, the extraction and regeneration engine 318 automatically extracts the necessary inputs for the modified ATG 314, i.e., the seed 206, profile settings 212, and command line settings 308. The extraction and regeneration engine 318 may be implemented using a suitable software language such as C, C++, or Perl, for example.

The extraction files 320 are employed by the random number generator 204 and the event probability generator 210 to generate the random number sequence 208 and probability profile 214, respectively, required to generate the modified test case 316. In particular, the seed 206 supplied to the random number generator 204 is the same seed 206 supplied to the random number generator 204 in FIG. 2. For example, if the seed 206 used to ultimately generate the test case 216 of FIG. 2 was equal to A, then the seed 206 used to ultimately generate the modified test case 316 is equal to A. Continuing with this example, the random number sequence 208 generated by the random number generator 204 in FIG. 2 would have been {A₁, A₂, A₃, . . . , Aₙ} and the random number generator 204 generates the same random number sequence 208 {A₁, A₂, A₃, . . . , Aₙ} using the extracted seed. Similarly, the profile settings 212 and command line settings 308 supplied to the modified ATG in order to generate the modified test case 316 are identical to the profile settings 212 and the command line settings 308 previously used to generate the test case 216. Therefore, the systems and methods disclosed herein provide the modified ATG 314 the same inputs as the ATG 202 in order to retest the processor models 218 with the modified test case 316 which is identical to the test case 216, but for the modifications made in order to eliminate the illegal test behavior. In particular, the ATG 202 cooperates with the extraction and regeneration engine 318 to provide this automated scheme of testing. As explained previously, the ATG 202 operates responsive to settings indicative of the seed 206, profile settings 212, and command line settings 308 in the test case 216 so that the settings will be embedded in the test files 224. The extraction regeneration engine 318 can then automatically extract and reconstruct the seed 206, profile settings 212, and command line settings 308 from settings embedded in the test structure 310. With this scheme, the systems and methods disclosed herein provide for efficient circuit design testing and minimize the labor associated with reconstructing the inputs originally supplied to the ATG 202.

By way of implementation, if an illegal test case is called test100.tc and the new, modified version of the ATG is located at /usr/bin/testgen, then the automatic extraction and regeneration process may be effectuated by calling out a script, e.g., “regen,” and executing a modified test case as follows:
regen test100.tc /usr/bin/testgen

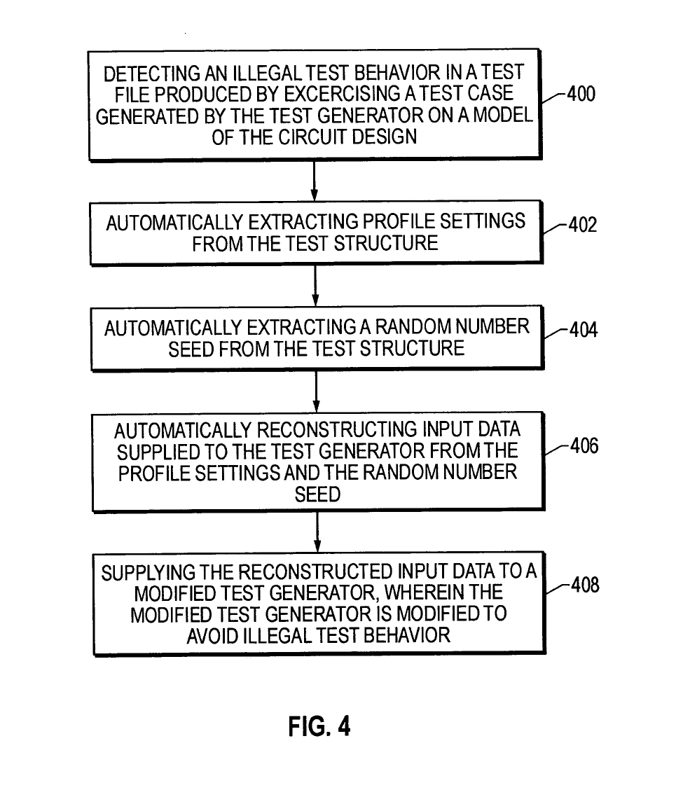

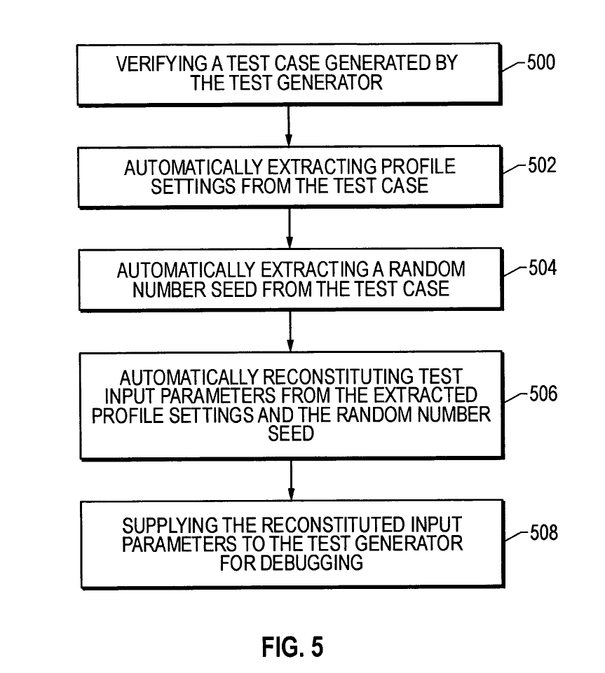

As may be appreciated by those skilled in the art, additional software functionalities can also be provided (for example, via software switches, dynamically linkable module options, and the like) to customize or further modify the dynamics of the extraction and regeneration process described herein. It should be appreciated from the foregoing description of FIG. 3 that the extraction and regeneration engine may be utilized for multiple purposes relating to reconstructing test case input parameters. Specifically, the extraction and regeneration engine may be employed to debug the ATG by automatically extracting and reconstituting the test input parameters, i.e., the seed and the profile settings, so that the ATG may be debugged. Additionally, the extraction and regeneration engine may be employed to supply a modified ATG, i.e., an ATG modified to remove illegal test behavior, reconstructed input data so that a modified test case may be generated for re-exercising the processor models. The following Figures, FIG. 4 and FIG. 5, illustrate these two aspects in additional detail.

FIG. 4 depicts a method of testing a circuit design using a test generator according to one embodiment. At block 400, an illegal test behavior is detected in a test file that is produced by exercising a test case generated by the test generator on a model of the circuit design. At block 402, profile settings are extracted from a test structure relating to the test case, e.g., the test file or the test case itself. At block 404, a random number seed is extracted from the test structure. Additional information such as command line settings may also be extracted from the test structure. It should be appreciated that the extraction operations of blocks 402 and 404 may occur in any order or simultaneously. Moreover, the extraction operations of blocks 402 and 404 may occur automatically in order to maximize the efficiency of testing operations. At block 406, input data supplied to the test generator is reconstructed from the profile settings and the random number seed. At block 408, the reconstructed input data is supplied to a modified test generator that has been modified to avoid illegal test behavior.

FIG. 5 depicts one embodiment of a method of debugging a test generator. At block 500, a test case generated by the test generator is verified, for example, by executing the test case on a processor model. At block 502, profile settings are automatically extracted from the test case. At block 504, a random number seed is automatically extracted from the test case. It should be appreciated that the operations of blocks 502 and 504 may be performed in any order or simultaneously. At block 506, test input parameters are automatically reconstituted from the extracted profile settings and the random number seed. Additionally, command line settings may be extracted as a portion of the input parameters. At block 508, the reconstituted input parameters are supplied to the test generator for debugging thereof by a comparator which may be a programmer, a group of programmers, an expert system or any combination thereof.

Although the invention has been particularly described with reference to certain illustrations, it is to be understood that the forms of the invention shown and described are to be treated as exemplary embodiments only. Various changes, substitutions and modifications can be realized without departing from the spirit and scope of the invention as defined by the appended claims.

1. A system for testing a circuit design using a test generator, comprising:
a random number generator, operating responsive to a seed, for generating a random number sequence;
an event probability generator, operating responsive to profile settings, for generating a probability profile,
wherein said test generator, responsive to said random number sequence and said probability profile, is operable to generate a test case that includes settings indicative of said seed and said profile settings, said test case for exercising a model of said circuit design; and
an extraction and regeneration engine operable to extract said seed and said profile settings from a test structure related to said test case in order to generate a reconstituted test case for further testing of said circuit design.

2. The system as recited in claim 1, wherein said seed and said profile settings are extracted from said test structure in order to provide said extracted seed and profile settings to a modified test generator, wherein said modified test generator is modified to avoid illegal test behavior with respect to said test case.

3. The system as recited in claim 1, wherein said test structure comprises said test case.

4. The system as recited in claim 1, wherein said test structure comprises a test file generated upon executing said test case on said circuit design.

5. The system as recited in claim 1, wherein said circuit design model comprises a simulated processor model that simulates the behavior of said circuit design with software.

6. The system as recited in claim 1, wherein said circuit design model comprises a processor core including at least one processor for operating at least one thread.

7. The system as recited in claim 1, wherein said circuit design model comprises a register-transfer level (RTL) model of an integrated circuit.

8. The system as recited in claim 1, wherein said circuit design model comprises an architectural simulation model of an integrated circuit.

9. The system as recited in claim 1, wherein said profile settings relate to controlling the probability of an event selected from the list of events consisting of loading, storing, arithmetic operations, and floating-point operations.

10. The system as recited in claim 1, wherein said extraction and regeneration engine is operable to extract command line settings from said test structure.

11. The system as recited in claim 1, wherein said test structure comprises a test file that contains at least one illegal test behavior.

12. The system as recited in claim 1, wherein said extraction and regeneration engine is implemented in a software language selected from the group consisting of a C, C++, and Perl.

13. A method of testing a circuit design using a test generator, comprising:
detecting an illegal test behavior in a test file produced upon exercising a test case generated by the test generator on a model of the circuit design;
extracting profile settings from a test structure relating to said test case;
extracting a random number seed from said test structure;
reconstructing input data supplied to said test generator from said profile settings and said random number seed extracted from said test structure; and
supplying said reconstructed input data to a modified test generator, wherein said modified test generator is modified to avoid said illegal test behavior.

14. The method as recited in claim 13, wherein the operations of extracting profile settings, extracting a random number seed, and reconstructing input data are performed automatically.

15. The method as recited in claim 13, further comprising employing a comparator to modify said test generator to produce said modified test generator.

16. The method as recited in claim 13, further comprising debugging said test generator.

17. The method as recited in claim 13, further comprising extracting command line settings from said test structure.

18. The method as recited in claim 17, wherein the operation of reconstructing input data comprises reconstructing input data supplied to said test generator from said profile settings, said random number seed, and said command line settings.

19. A computer system operable to simulate a platform for testing a circuit design, the computer system comprising:
test generator means for generating a test case using a random number seed and an event probability profile, said test case for executing on a model associated with said circuit design;
means for extracting and regenerating said random number seed and said event probability profile from a test structure relating to said test case; and
means for automatically retesting said circuit design model using a reconstituted test case based on said extracted random number seed and event probabilities profile.

20. The computer system as recited in claim 19, wherein said circuit design model comprises a simulated processor model that simulates the behavior of said circuit design with software.

21. The computer system as recited in claim 19, wherein said circuit design model comprises a processor core including at least one processor for operating at least one thread.

22. The computer system as recited in claim 19, wherein said circuit design model comprises a register-transfer level (RTL) model of an integrated circuit.

23. The computer system as recited in claim 19, wherein said circuit design model comprises an architectural simulation model of an integrated circuit.

24. The computer system as recited in claim 19, wherein said profile settings relate to controlling the probability of an event selected from the list of events consisting of loading, storing, arithmetic operations, and floating-point operations.

25. The computer system as recited in claim 19, wherein said reconstituted test case is further based on command line settings extracted from said test structure.

26. The computer system as recited in claim 19, wherein said test structure comprises a test file containing at least one illegal test behavior, said test file being generated upon executing said test case on said circuit design model.

27. A system for testing a circuit design using a test generator, comprising:
means for detecting an illegal test behavior in a test file produced upon exercising a test case generated by the test generator on a model of the circuit design;
means for extracting profile settings from a test structure relating to said test case;
means for extracting a random number seed from said test structure;
means for reconstructing input data supplied to said test generator from said profile settings and said random number seed; and
means for supplying said reconstructed input data to a modified test generator, wherein said modified test generator is modified to avoid said illegal test behavior.

28. The system as recited in claim 27, wherein said means for extracting profile settings, means for extracting a random number seed, and means for reconstructing input data operate automatically.

29. The system as recited in claim 27, further comprising comparator means to modify said test generator to produce said modified test generator.

30. The system as recited in claim 27, further comprising means for debugging said test generator.

31. The system as recited in claim 27, further comprising means for extracting command line settings from said test structure.

32. The system as recited in claim 31, wherein said means for reconstructing input data comprises means for reconstructing input data supplied to said test generator from said profile settings, said random number seed, and said command line settings.

33. A method for debugging a test generator, comprising:
verifying a test case generated by said test generator;
automatically extracting profile settings from said test case;
automatically extracting a random number seed from said test case;
automatically reconstituting test input parameters from said extracted profile settings and said random number seed; and
supplying said reconstituted input parameters to said test generator for debugging.

34. The method as recited in claim 33, further comprising extracting command line settings from said test case.

35. The method as recited in claim 34, wherein the operation of automatically reconstituting input parameters from said extracted profile further comprises automatically reconstituting test input parameters from said extracted profile settings, said random number seed, and said command line settings.

36. The method as recited in claim 34, wherein the operation of supplying said reconstituted input parameters to said test generator for debugging further comprises supplying said reconstituted input parameters to said test generator for debugging by a comparator.

37. A system for debugging a test generator, comprising:
means for verifying a test case generated by said test generator;
means for automatically extracting profile settings from said test case;
means for automatically extracting a random number seed from said test case;
means for automatically reconstituting test input parameters from said extracted profile settings and said random number seed; and
means for supplying said reconstituted input parameters to said test generator for debugging.

38. The system as recited in claim 37, further comprising means for extracting command line settings from said test case.

39. The system as recited in claim 38, wherein said means for automatically reconstituting input parameters from said extracted profile further comprises means for automatically reconstituting test input parameters from said extracted profile settings, said random number seed, and said command line settings.

40. The system as recited in claim 37, wherein said means for supplying said reconstituted input parameters to said test generator for debugging further comprises means for supplying said reconstituted input parameters to said test generator for debugging by a comparator.

41. A computer-readable medium operable with a computer platform for testing a circuit design using a test generator, the medium having stored thereon:
instructions for detecting an illegal test behavior in a test file produced upon exercising a test case generated by the test generator on a model of the circuit design;
instructions for extracting profile settings from a test structure relating to said test case;
instructions for extracting a random number seed from said test structure;
instructions for reconstructing input data supplied to said test generator from said profile settings and said random number seed extracted from said test structure; and
instructions for supplying said reconstructed input data to a modified test generator, wherein said modified test generator is modified to avoid said illegal test behavior.

42. A computer-readable medium operable with a computer platform for debugging a test generator, the medium having stored thereon:
instructions for verifying a test case generated by said test generator;
instructions for automatically extracting profile settings from said test case;
instructions for automatically extracting a random number seed from said test case;
instructions for automatically reconstituting test input parameters from said extracted profile settings and said random number seed; and
instructions for supplying said reconstituted input parameters to said test generator for debugging.
